(19) United States
(12) Patent Application Publication
(10) Pub. No.: US 2025/0013809 A1
(43) Pub. Date: Jan. 9, 2025

(54) CARBON MEASUREMENT METHOD FOR UNORGANIZED EMISSIONS OF GREENHOUSE GASES IN INDUSTRIAL PARK

(71) Applicant: Chengdu Schrodinger Energy Carbon Technology Co., Ltd., Chengdu (CN)

(72) Inventors: Ning DING, Chengdu (CN); Yanheng XI, Chengdu (CN); Jun SU, Chengdu (CN); Wenting JIANG, Chengdu (CN)

(73) Assignee: Chengdu Schrodinger Energy Carbon Technology Co., Ltd., Chengdu (CN)

(21) Appl. No.: 18/381,177

(22) Filed: Oct. 18, 2023

(30) Foreign Application Priority Data
Jul. 3, 2023 (CN) 202310804420.4

(51) Int. Cl. G06F 30/28; G06F 30/27

(52) U.S. Cl. CPC G06F 30/28; G06F 30/27

(57) ABSTRACT

A carbon measurement method for unorganized emissions of greenhouse gas in industrial parks. Through random forest machine learning, combining with cubic spline interpolation and BP neural network to optimize the thought of interpolation, obtaining the influencing factors, and outputting the evaluation report of the impact of the prediction model and meteorological environment on unorganized emissions, obtaining the input variables in the simulation model, Combining equations for simulation, thereby obtaining a specific flow value of unorganized emissions at a certain moment, then multiplying by the concentration of unorganized greenhouse for gas emission, and obtaining carbon emissions, so as to realize the carbon measurement of unorganized emission in industrial parks.

### CROSS REFERENCE TO THE RELATED APPLICATIONS

This application is based upon and claims priority to Chinese Patent Application No. 2023108044204, tiled on Jul. 3, 2023, the entire contents of which are incorporated herein by reference.

### TECHNICAL FIELD

The present invention relates to the technical field of greenhouse gas carbon emission, in particular to a carbon measurement method for unorganized emissions of greenhouse gas in industrial parks.

### BACKGROUND

It is difficult to monitor the unorganized emissions of greenhouse gases in industrial parks, and it is difficult to measure the carbon emissions of unorganized emissions, because unorganized emissions are affected by environmental impact and terrain, at present, the monitoring of greenhouse gas unorganized emissions in industrial parks is basically carried out through the steps of adjusting working conditions, measuring meteorological parameters at points, connecting sampling systems, and analyzing after sampling. However, this method is easily affected by human factors and environmental factors, resulting in errors and low accuracy; sampling equipment and positioning meteorological parameters require higher economic costs; the measuring meteorological parameters at points and laboratory analysis need a lot of manpower and material resources; as well as the need for professionals to carry out a series of tedious operations after training; there are many shortcomings, so far there is no mature theoretical system, so it has brought great challenges to the measurement of unorganized carbon emissions.

### SUMMARY

The present invention provides a carbon measurement method for unorganized emissions of greenhouse gas in industrial parks, solving the objective shortcomings of the existing technology, based on the historical unorganized emission data and meteorological data of the industrial park, combined with the thought of cubic spline interpolation, back-propagation (BP) neural network and random forest algorithm, on this basis, the Ansys Fluent simulation model is combined, which saves cost and achieves high-precision prediction, it can also train an unstructured emission prediction model with the strongest generalization ability, a reasonable environmental factor evaluation index, and realize the carbon measurement of unorganized emissions in industrial parks.

To achieve the above purpose, the present invention adopts the following technical scheme:
a carbon measurement method for unorganized emissions of greenhouse gas in industrial parks, including the following steps:
S1. obtaining historical meteorological data and historical carbon emission data of an industrial park, under the support of meteorological theory, dividing the historical meteorological data into three categories, and describing the meteorological data by cubic spline interpolation;
S2. on the basis of classification, obtaining the meteorological data which are difficult to measure and have great influence by interpolation surface, and inputting the obtained meteorological data into BP neural network for strengthening.
S3. inputting the enhanced meteorological data into the random forest algorithm for accurate prediction, determining whether the prediction accuracy meets the needs of actual industrial parks and related industry standards and laws and regulations for unorganized emission monitoring, if the requirements are met, outputting the prediction results and prediction models, which is the prediction model with the strongest generalization ability;
S4. according to different classifications, carrying out the weight analysis of the important degree quantitative index of the input parameters of Ansys Fluent;
S5. establishing the Ansys Fluent simulation model of industrial park is established, and importing the parameters after weight analysis into the Ansys Fluent simulation model;
S6. obtaining the unorganized emission flow of greenhouse gases at a certain time node in the industrial park, obtaining the unorganized emission concentration of greenhouse gases from the sensor, obtaining carbon emissions of greenhouse gas in industrial parks, and realizing the carbon measurement for unorganized emissions in industrial parks;
S7. outputting the random forest prediction model with the strongest generalization ability and the environmental impact factor evaluation report.

Preferably, three categories of meteorological data in step S1 include:
the first category: sensible heat flux, potential temperature gradient, surface ripple ratio, surface reflectivity at noon, air temperature, temperature measurement height, humidity, radiation loss rate, and total heat release rate;
the second category: surface friction velocity, convective velocity scale, convective boundary layer height, mechanical atmospheric boundary layer height, surface roughness, wind speed, wind direction, wind measurement height, humidity;
the third category: Mani length, surface pressure, low-capacity, humidity, temperature, industrial park latitude and longitude, elevation and other geographic information.

Preferably, for the first category of meteorological data, where the data that has the greatest impact on unorganized emissions is sensible heat flux, through a thought of interpolation, describing a sensible heat flux of temperature at the corresponding time node, by interpolation surface, obtaining a sensible heat flux corresponding to a certain temperature value on the corresponding time node accurately.

Preferably, for the second category of meteorological data, where the data with the greatest impact on unorganized emissions are surface friction velocity and mechanical atmospheric boundary layer height, through a thought of interpolation, obtaining the surface friction velocity and mechanical atmospheric boundary layer height of the wind speed at the corresponding time node, by interpolation surface, obtaining the surface friction velocity and mechanical atmospheric boundary layer height under a certain wind speed condition at the corresponding time node accurately.

Preferably, for the third category of meteorological data, wherein the data that has the greatest impact on unorganized emissions is the Mani length, using a thought of interpolation fitting, fitting out the Mani length of humidity at the corresponding time node, by interpolation surface, obtaining the Mani length corresponding to a humidity value on the corresponding time node accurately.

Preferably, the data enhancement of BP neural network in step S2 is specified as: putting the parameter values obtained by interpolation surface into the whole category of meteorological factors respectively for learning reinforcement, repairing and strengthening the missing data and error data that affect the key meteorology on the basis of relevant meteorological theories, making the reduction degree of this kind of data reach more than 90%.

Preferably, the weight analysis in step S4 is specified as: based on the prediction model in step S3 and the cubic spline interpolation function, combined with the average impurity reduction of random forest, quantifying the importance of important feature value, as well as the surface friction velocity, Mani length, sensible heat flux, mechanical atmospheric boundary layer height obtained by cubic spline interpolation, and the wind speed, wind direction, temperature and humidity measured by the sensor at low cost, quantifying these eight important parameters into quantitative indicators based on their importance, and then performing weight analysis.

Preferably, in Step S5, by using Navier-Stokes continuity equation, Navier-Stokes momentum equation, energy equation, relying on Ansys Fluent simulation software, combined with the parameters obtained by weight analysis, as the input of the model established by Ansys Fluent simulation software, obtaining a fluid flow model of unorganized emission in industrial park.

Preferably, in Step S6, multiplying the specific flow value of unorganized emissions at a certain moment by the concentration value for unorganized emissions of greenhouse gas measured by sensors, thereby obtaining a carbon measurement for unorganized emissions of greenhouse gas in industrial parks.

Therefore, the present invention adopts a carbon measurement method for unorganized emissions of greenhouse gas in industrial parks, and the beneficial effects achieved are:
1. economically: the required cost is low, saving the time for monitoring sampling and analysis of unorganized emissions, manpower and material resources, and improving economic benefits.
2. in terms of accuracy: in the unorganized emission prediction area based on this application prediction model, arranging a certain number of monitoring sensors, which can not only improve the accuracy of unorganized monitoring of industrial parks under the premise of objective science, but also reduce the cost of unorganized monitoring; making the accuracy of carbon measurement results meet the needs of relevant departments and laws and regulations.
3. in terms of complexity: based on the algorithm and easily available meteorological data, it is very easy to realize unorganized emission trend prediction and unorganized emission carbon measurement in industrial parks, simple operation, saving manpower and material resources.
4. operability: it only needs to import the easily measured data, convenient operation, improving the uncertainty and ability of control and mastery of unorganized emissions, meanwhile it can also provide an evaluation report on the environmental impact factors of greenhouse gases.

The following is a further detailed description of the technical scheme of the invention through the drawings and embodiments.

### BRIEF DESCRIPTION OF THE DRAWINGS

FIGS. 1A-1B show a flow chart of an example of a carbon measurement method for unorganized emissions of greenhouse gas in industrial parks of the present invention, the bottom of FIG. 1A is connected to the top of FIG. 1B by the arrow symbol at the bottom of FIG. 1A:

FIG. 2 is a distribution map of importance degree of meteorological parameter eigenvalues of the example of a carbon measurement method for unorganized emissions of greenhouse gas in industrial parks of a carbon measurement method for unorganized emissions of greenhouse gas in industrial parks of the present invention;

FIG. 3 is a diagram of the relationship between the temperature and sensible heat flux of the example of a carbon measurement method for unorganized emissions of greenhouse gas in industrial parks of the present invention;

FIG. 4 is a diagram of the relationship between wind speed and surface friction velocity of the example of a carbon measurement method for unorganized emissions of greenhouse gas in industrial parks of the present invention;

FIG. 5 is a diagram of the relationship between wind speed and mechanical atmospheric boundary layer height of the example of a carbon measurement method for unorganized emissions of greenhouse gas in industrial parks of the present invention;

FIG. 6 is a diagram of the relationship between the humidity and the mani length of the example of a carbon measurement method for unorganized emissions of greenhouse gas in industrial parks of the present invention;

FIG. 7 is an analysis diagram of the industrial park of the example of a carbon measurement method for unorganized emissions of greenhouse gas in industrial parks of the present invention;

FIG. 8 is an analysis diagram of the industrial park of the example of a carbon measurement method for unorganized emissions of greenhouse gas in industrial parks of the present invention;

FIG. 9 is an analysis diagram of the industrial park of the example of a carbon measurement method for unorganized emissions of greenhouse gas in industrial parks of the present invention.

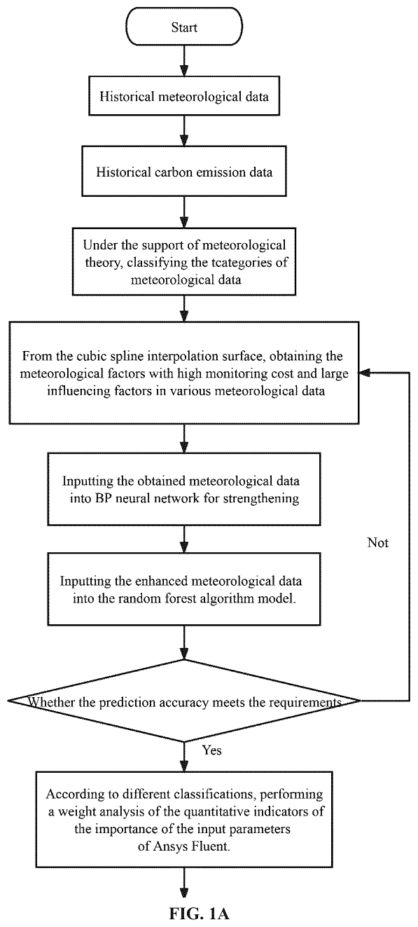

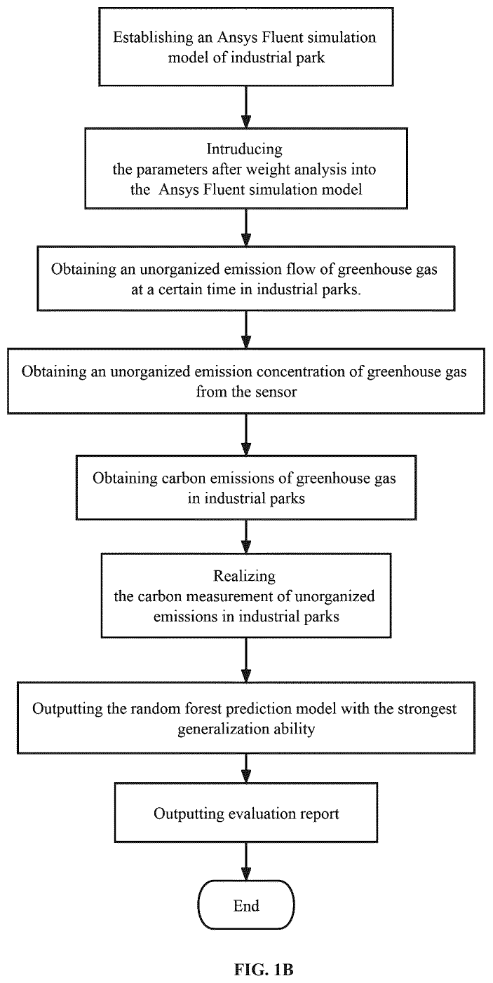

### DETAILED DESCRIPTION OF THE EMBODIMENTS

The technical scheme of the invention is further explained below by drawings and embodiments.

Unless otherwise defined, the technical terms or scientific terms used in the invention shall be understood by persons with general skills in the field to which the invention belongs. The words ‘first’, ‘second’, and the like used in this invention do not represent any order, quantity, or importance, but are only used to distinguish different components. Similar words such as ‘including’ or ‘comprising’ mean that the elements or objects in front of the word cover the elements or objects listed after the word and their equivalents, without excluding other elements or objects. The terms ‘set’, ‘installation’ and ‘connection’ should be understood in a broad sense. For example, they can be fixed connection, detachable connection, or integrated connection: it can be mechanical connection or electrical connection; it can be directly connected or indirectly connected through an intermediate medium, which can be the internal connection of two components; ‘up’, ‘down’, ‘left’, ‘right’ etc. are only used to represent the relative positional relationship. When the absolute position of the described object changes, the relative positional relationship may also change accordingly.

### EXAMPLE

As shown in the figures, the present invention provides a carbon measurement method for unorganized emissions of greenhouse gas in industrial parks, which includes the following steps:
S1 obtaining historical meteorological data and historical carbon emission data of an industrial park, under the support of meteorological theory, dividing the historical meteorological data into three categories, and describing the meteorological data cubic spline interpolation;
S2. on the basis of classification, obtaining the meteorological data which are difficult to measure and have great influence by interpolation surface, and inputting the obtained meteorological data into BP neural network for strengthening.
S3. inputting the enhanced meteorological data into the random forest algorithm for accurate prediction, determining whether the prediction accuracy meets the needs of actual industrial parks and related industry standards and laws and regulations for unorganized emission monitoring, if the requirements are met, outputting the prediction results and prediction models, which is the prediction model with the strongest generalization ability;
S4. according to different classifications, carrying out the weight analysis of the important degree quantitative index of the input parameters of Ansys Fluent:
S5. establishing the Ansys Fluent simulation model of industrial park is established, and importing the parameters after weight analysis into the Ansys Fluent simulation model;
S6. obtaining the unorganized emission flow of greenhouse gases at a certain time node in the industrial park, obtaining the unorganized emission concentration of greenhouse gases from the sensor, obtaining greenhouse gas carbon emissions in industrial parks, and realizing the measurement of unorganized carbon emissions in industrial parks;
S7. outputting the random forest prediction model with the strongest generalization ability and the environmental impact factor evaluation report.

The three categories of meteorological data in step S1 include:
the first category: sensible heat flux, potential temperature gradient, surface ripple ratio, surface reflectivity at noon, air temperature, temperature measurement height, humidity, radiation loss rate, total heat release rate:
the second category: surface friction velocity, convective velocity scale, convective boundary layer height, mechanical atmospheric boundary layer height, surface roughness, wind speed, wind direction, wind measurement height, humidity;
the third category: Mani length, surface pressure, low-capacity, humidity, temperature, industrial park latitude and longitude, elevation and other geographic information.

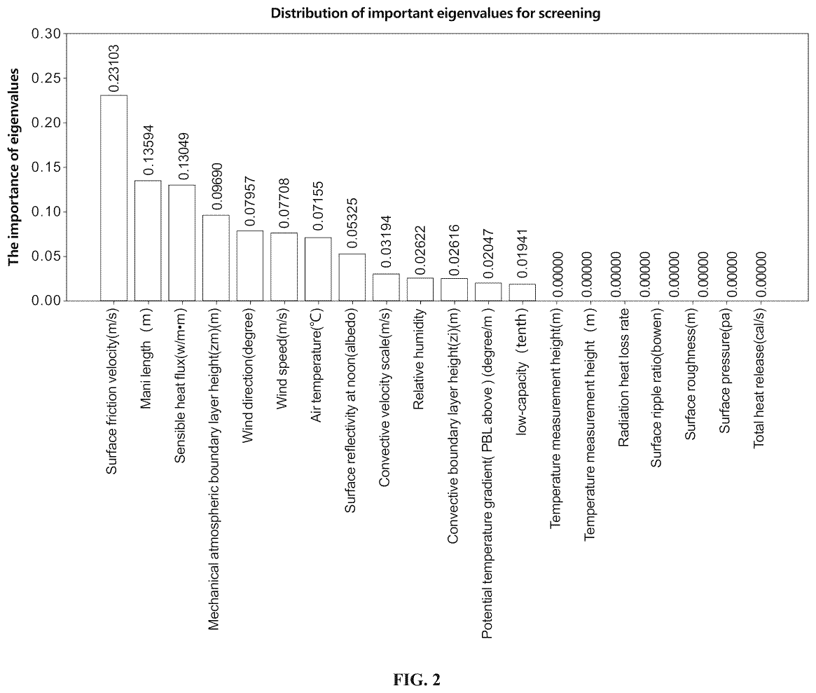

As shown in FIG. 2, among the three types of meteorological data, surface friction velocity, Mani length, sensible heat flux, mechanical atmospheric boundary layer height, wind direction, wind speed, air temperature and humidity are the key meteorological factors (the influence degree of the eight factors decreases in the order mentioned above).

The present invention provides a carbon measurement method for unorganized emissions of greenhouse gas in industrial parks, describing three types of data by cubic spline interpolation, and the specific formulas are as follows:
By: Sᵢ(xᵢ)=aᵢ+bᵢ (x−xᵢ)+cᵢ(x−xᵢ)²+dᵢ(x−xᵢ)=yᵢ
Get: αᵢ=yᵢ
Sᵢ(xᵢ): represents the function of cubic spline difference
aᵢ, bᵢ, cᵢ, dᵢ: denotes the undetermined coefficient at point i.

Let hᵢ=xᵢ₊₁−xᵢ denote the step length,
Available: aᵢ+hbᵢ cᵢh² dᵢh³=yᵢ₊₁
hᵢ: represents step length
By Sᵢ′(xᵢ₊₁)=Sᵢ₊₁′(xᵢ₊₁) get:

$${S}_{i}^{′} ( {x}_{i + 1} ) = {b}_{i} + 2 {c}_{i} ( {x}_{i + 1} - {x}_{i} ) + 3 {{d}_{i} ( {x}_{i + 1} - {x}_{i} )}^{2} = {b}_{i} + 2 {c}_{i} h + 3 {d}_{i} {h}^{2} \\ {S}_{i + 1}^{′} ( {x}_{i + 1} ) = {b}_{i + 1} + 2 {c}_{i} ( {x}_{i + 1} - {x}_{i + 1} ) + 3 {{d}_{i} ( {x}_{i + 1} - {x}_{i + 1} )}^{2} = {b}_{i + 1}$$

S′: represents the first derivative at this point
get bᵢ+2cᵢhᵢ+3dᵢhᵢ²=bᵢ₊₁
By Sᵢ″(xᵢ₊₁)=Sᵢ₊₁″(xᵢ₊₁), get 2cᵢ+6dᵢhᵢ=2cᵢ₊₁
Set: Sᵢ″(xᵢ)=2cᵢ=mᵢ, get:

$${d}_{i} = \frac{{m}_{i + 1} - {m}_{i}}{6 {h}_{i}}$$

S″: represents the second derivative at this point
the above conclusions are brought into aᵢ+hbᵢ+cᵢh² dᵢh³=yᵢ₊₁ get:

$${h}_{i} {m}_{i} + 2 ( {h}_{i} + {h}_{i + 1} ) {m}_{i + 1} + {h}_{i + 1} {m}_{i + 2} = 6 [ \frac{{y}_{i + 2} - {y}_{i + 1}}{{h}_{i + 1}} - \frac{{y}_{i + 1} - {y}_{i}}{{h}_{i}} ]$$

In summary
In each subinterval xᵢ≤x≤xₓ₊₁, the equation that can be created is:

$${g}_{i} ( x ) = {y}_{i} + ( \frac{{y}_{i + 1} - y}{{h}_{i}} - \frac{{h}_{i}}{2} {m}_{i} - \frac{{h}_{i}}{6} ( {m}_{i + 1} - {m}_{i} ) ) ( x - {x}_{i} ) + \frac{{m}_{i}}{2} {( x - {x}_{i} )}^{2} + ( \frac{{m}_{i + 1} - {m}_{i}}{6 {h}_{i}} ) {( x - {x}_{i} )}^{3}$$

gᵢ(x): represents the value corresponding to point i after fitting by cubic spline interpolation.

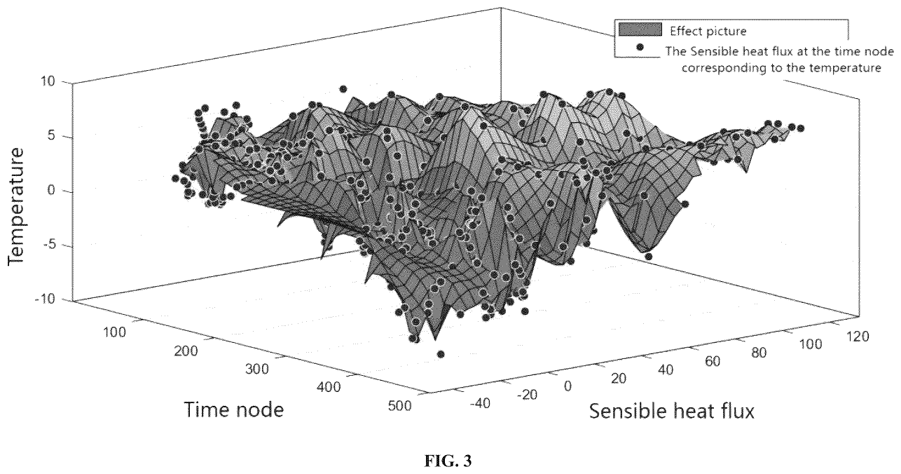

As shown in FIG. 3, for the first category of meteorological data, wherein the meteorological condition that has the greatest impact on unorganized emissions is sensible heat flux, however, due to its difficulty in monitoring and high cost, it is not conducive to the actual prediction of unorganized emission in industrial parks; but the air temperature has a greater correlation with the sensible heat flux, because cubic sample interpolation has better fitting data properties, it can approximate the fitting surface by the polynomial high term, which makes the interpolation around the advantages of high approximate zero degree, through the thought of interpolation, describing the sensible heat flux of temperature at the corresponding time node of temperature;

By interpolation surface, obtaining accurately the sensible heat flux corresponding to a certain temperature value at the corresponding time (time node), for example, when an industrial park predicts or monitors unorganized emissions, it is not necessary to provide the specific parameter value of sensible heat flux, only by providing the temperature value at a certain moment, the sensible heat flux corresponding to that moment can be obtained through the above interpolation surface.

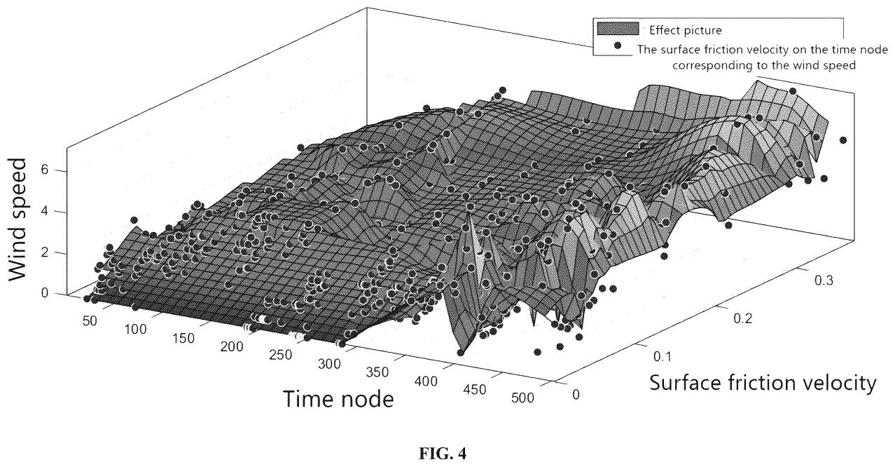

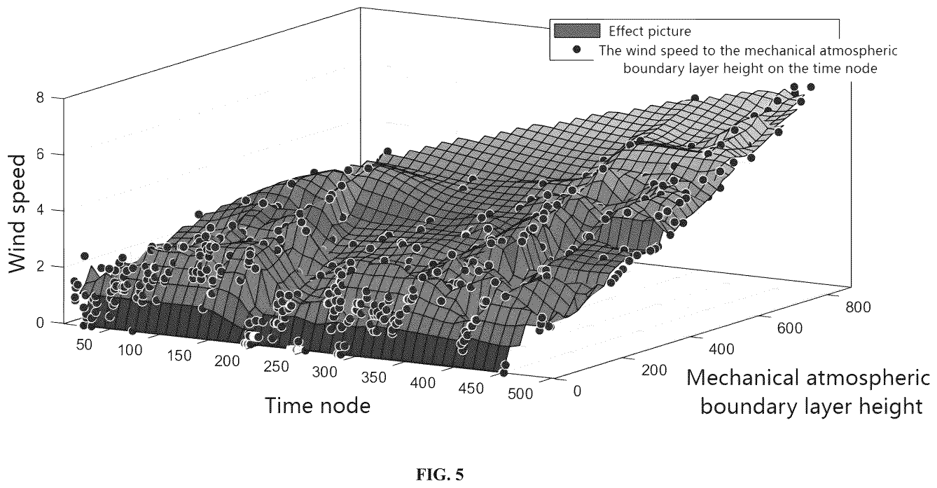

As shown in FIGS. 4-5, for the second category of meteorological data, wherein surface friction velocity and mechanical atmospheric boundary layer height have the greatest influence on unorganized emissions, but the monitoring of both is very difficult, it requires the use of specific meteorological observation equipment and professional knowledge and skills support, the monitoring cost is high and the difficulty is large; the wind speed has a greater correlation with the two, therefore, through the thought of interpolation, obtaining the surface friction velocity and mechanical atmospheric boundary layer height of the wind speed at the corresponding time node.

By interpolation surface, obtaining accurately the surface friction velocity and mechanical atmospheric boundary layer height under a certain wind speed condition at the corresponding time (time node), for example, when an industrial park predicts and monitors unorganized emissions, it is not necessary to collect the parameter values of surface friction velocity and mechanical atmospheric boundary layer height on the basis of high cost, only need to provide the wind speed value at a certain time, obtaining the surface friction velocity and the mechanical atmospheric boundary layer height corresponding to the time by the above thought of interpolation surface.

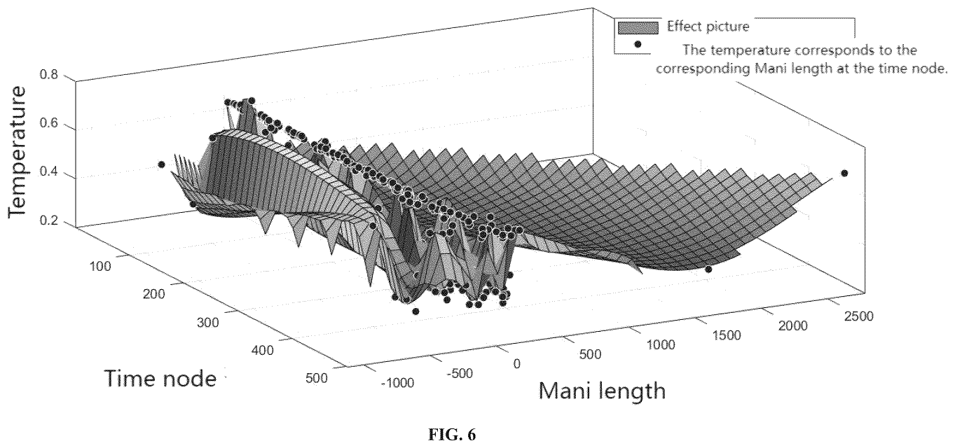

As shown in FIG. 6, for the third category of meteorological data, wherein the meteorological condition that has the greatest impact on unorganized emissions is the Mani length, however, the monitoring cost of the Mani length is high, and the Mani length needs to collect a variety of monitoring types of equipment for comprehensive analysis, so it is difficult to monitor, and the humidity has a great correlation with the Mani length, therefore, Fitting the Mani length of humidity at the corresponding time node by using the thought of interpolation fitting;

By interpolation surface, accurately obtaining the Mani length corresponding to a certain humidity value at the corresponding time (time node), for example, when an industrial park predicts or monitors unorganized emissions, it does not need to provide the specific parameter values of the Mani length, but only needs to provide the humidity value at a certain moment, through the above interpolation surface, obtaining the Mani length corresponding to this time.

Through the above three classifications, and the thought of using interpolation surfaces for various meteorological conditions respectively, on the basis of meteorological conditions that are easier to monitor, such as temperature, wind speed, wind direction, and humidity, obtaining meteorological conditions that are not easy to monitor at the corresponding time, have high monitoring costs, and have a great impact on unorganized emissions, for example: surface friction velocity, Mani length, sensible heat flux, mechanical atmospheric boundary layer height.

That is, this application can obtain meteorological parameters that play a key role in unorganized emissions at a lower cost, they are respectively: surface friction velocity, Mani length, sensible heat flux, mechanical atmospheric boundary layer height, wind direction, wind speed, temperature, humidity, etc.

Step S2 uses BP neural network to strengthen the above meteorological data, namely the characteristic value, that is to say, putting the parameter values obtained by interpolation surface into the whole category of meteorological factors for learning reinforcement, for the missing data and error data that affect the key weather, on the basis of relevant meteorological theories, repairing and strengthening so that the data reduction degree reaches more than 90%.

Then, Steps S3 and S4 can input the above meteorological factors into the random forest model to predict the unorganized emissions. then judging whether the prediction accuracy of unorganized emissions obtained by the meteorological factors after interpolation surface acquisition and BP enhancement in the random forest prediction model meets the relevant requirement, if the requirements are met, outputting prediction results and the prediction model, that is, it is the prediction model with the strongest generalization ability, and based on this model and cubic spline interpolation function, combined with the average impurity reduction of random forest, quantifying the importance of important feature value, as well as the surface friction velocity, Mani length, sensible heat flux, mechanical atmospheric boundary layer height obtained by cubic spline interpolation, and the wind speed, wind direction, temperature and humidity measured by the sensor at low cost, quantifying these eight important parameters into quantitative indicators based on their importance, and then performing weight analysis, the specific formula is as follows.

The calculation formula of information entropy in random forest:

$$Entropy ( D ) = - {\sum }_{m}^{i = 1} ( \vert {D}_{i} \vert / N ) * {log}_{2} ( \vert {D}_{i} \vert / N ) \\ Entrop ( D / A ) = {\sum }_{m}^{i = 1} ( \vert {D}_{i} \vert / N ) * Entrop ( {D}_{i} ) \\ INFgain ( D , A ) = Entropy ( D ) - Entropy ( D / A )$$

   |Di represents the number of samples in subset Di;
Entropy(Di) represents the entropy of subset Di;
Entropy(D) is the entropy of data set), Entropy(D|A) is the conditional entropy after feature division.

Combined with FIG. 2, the weight analysis formula of important influencing factors is:

$${y}_{i} = \frac{{\sum }_{m}^{i = 1} {a}_{i} * {x}_{i}}{{\sum }_{m}^{i = 1} a}$$

αᵢ is the weight value of each influencing factor;
m is the number of influencing factors in a large class:
xᵢ is the specific value of a large class of influencing factors and the value obtained by cubic spline interpolation fitting;
yᵢ is the specific value obtained after weight analysis.

Because there is no mature theoretical system for carbon measurement in unorganized emissions, the unorganized emissions of greenhouse gases are greatly affected by meteorological factors, which brings great challenges to the carbon measurement of unorganized emissions, therefore, this application step S5 and step S6 use Navier-Stokes continuity equation, Navier-Stokes momentum equation, energy equation, etc., relying on Ansys-fluent simulation software, combined with the weight analysis of step S4, obtaining the wind speed, temperature, humidity and other parameters which are used as the input of the model established by Ansys-fluent software, obtaining a fluid flow model of unorganized emission in industrial park, so as to obtain the specific flow value of unorganized emissions at a certain moment, then multiplying with the concentration value for unorganized emission of greenhouse gas measured by the sensor, thereby accurately obtaining the carbon measurement of greenhouse gas unorganized emissions in industrial parks, where,
Navier-stokes equation:
the continuity equation, also known as the mass conservation equation or the divergence equation, describes the conservation of mass in fluid flow

$$u = {y}_{1} \\ ∇ \cdot ( ρ u ) = 0$$

V̅· represents divergence operation of vector, and represents calculating the gradient of each component of the vector and then summing;
ρ is the density of greenhouse gases;
u is velocity vector of greenhouse gases;
y₁ is velocity vector of greenhouse gases which is obtained by the weight analysis of the parameters in the second category according to the quantitative index of importance.

Momentum equation:
the momentum equation is used to describe the motion behavior of incompressible fluid under the action of force

$$u = {y}_{1} \\ ρ ( \frac{\partial u}{\partial t} + u \cdot ∇ u ) = - ∇ p + μ {∇}^{2 u} + ρ g$$

ρ is the fluid density;
u is the velocity vector of fluid;
y₁ is velocity vector of greenhouse gases which is obtained by the weight analysis of the parameters in the second category according to the quantitative index of importance;
∂u/∂t is the rate of change of velocity, which indicates the change of velocity per unit time;
V̅u is gradient of velocity, which indicates spatial change rate of velocity;
p is pressure;
μ is the dynamic viscosity of greenhouse gas fluid, which is used to describe the viscosity characteristics of greenhouse gas;
V̅^{2u} is the Laplace Operator of the velocity, which represents the second-order spatial derivative of velocity;
g is the vector of gravitational acceleration.

Energy equation:
the energy eluation is an equation used to describe the energy transfer and temperature change in air or fluid. In Ansys Fluent, the energy equation is used to simulate heat conduction, convection and possible radiative heat transfer in air flow,

$$u = {y}_{1} \\ T = {y}_{2} \\ ρ {C}_{P} ( \partial T / \partial t + u \cdot ∇ T ) = ∇ \cdot ( k ∇ T ) + Q$$

ρ is the density of air;
Cₚ is the constant pressure specific heat capacity of air, which represents the amount of heat absorbed or released by a change in the temperature of air per unit mass;
y₂ is the temperature of greenhouse gases which is obtained by the weight analysis of the parameters in the second category according to the quantitative index of importance;
T is the temperature of greenhouse gases;
∂T/∂t is the rate of change of greenhouse gas temperature over time;
y₁ is velocity vector of greenhouse gases which is obtained by the weight analysis of the parameters in the second category according to the quantitative index of importance;
u is the velocity vector of greenhouse gas;
V̅T is the gradient of greenhouse gas temperature;
k is the thermal conductivity of greenhouse gases, which represents the conductivity of heat per unit time and per unit area.
Q is the heat source or heat source term, which represents the heat generation or absorption per unit time and unit volume.

Through the above equation, Ansys Fluent can simulate and analyze the phenomenon of heat conduction and thermal convection in air flow, predicting the temperature distribution and heat transfer behavior in the flow field, thereby providing predictions and analysis results on the hydrodynamic characteristics of greenhouse gases, and simulating and analyzing the velocity distribution, pressure distribution and fluid flow behavior in incompressible greenhouse gases, thereby obtaining the unorganized greenhouse gas emission flow rate in the industrial park.

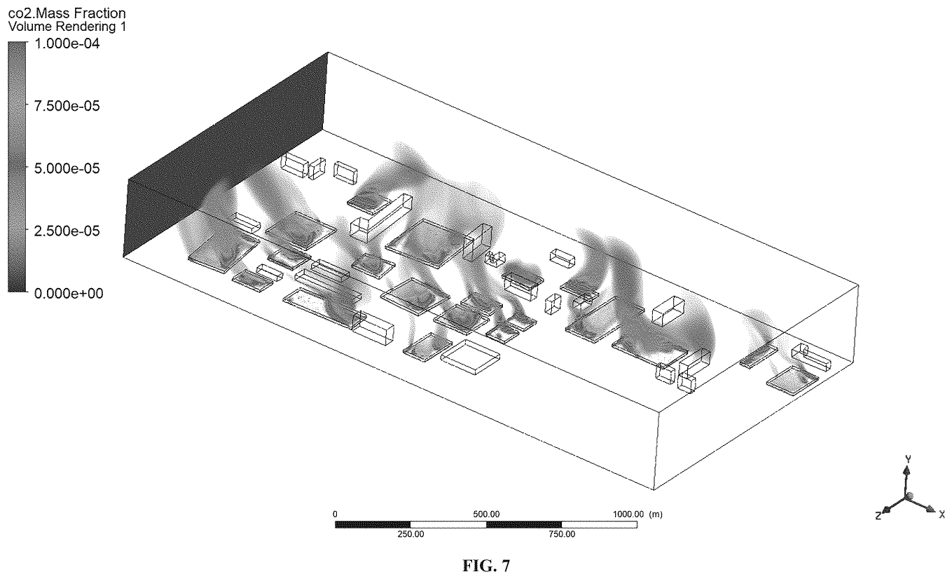

As shown in FIGS. 7-9, taking an industrial park as an example:

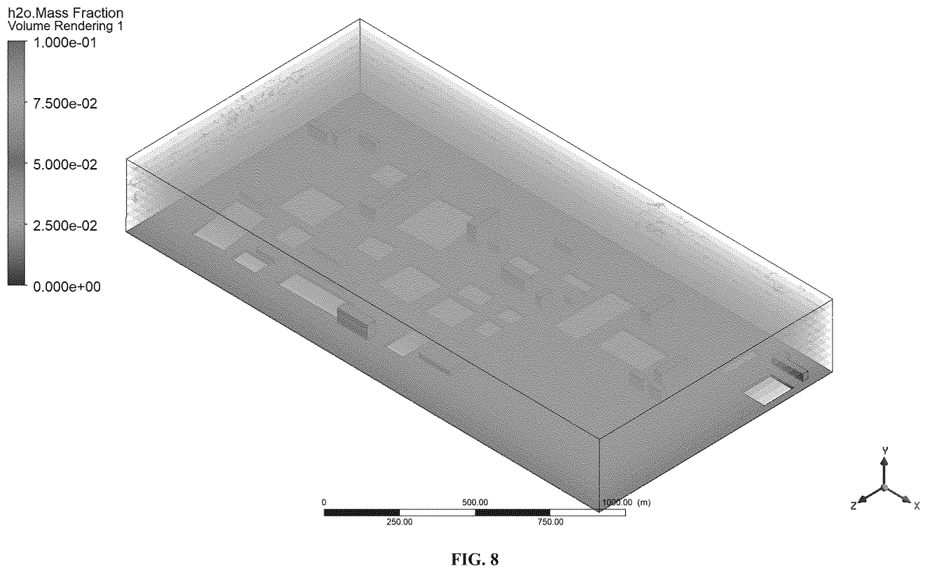

As shown in FIG. 7, using Ansys Fluent to simulate the unorganized emissions in the industrial park, the greenhouse gas velocity and temperature parameters input in the Ansys Fluent simulation model, performing weight analysis after quantifying the indicators according to the above importance and obtaining y₁,y₂:
as shown in FIG. 8, the industrial park humidity plant in the simulation model is through the formula

$${y}_{i} = \frac{{\sum }_{m}^{i = 1} {a}_{i} * {x}_{i}}{{\sum }_{m}^{i = 1} a} ,$$

obtaining the humidity distribution in the third category;

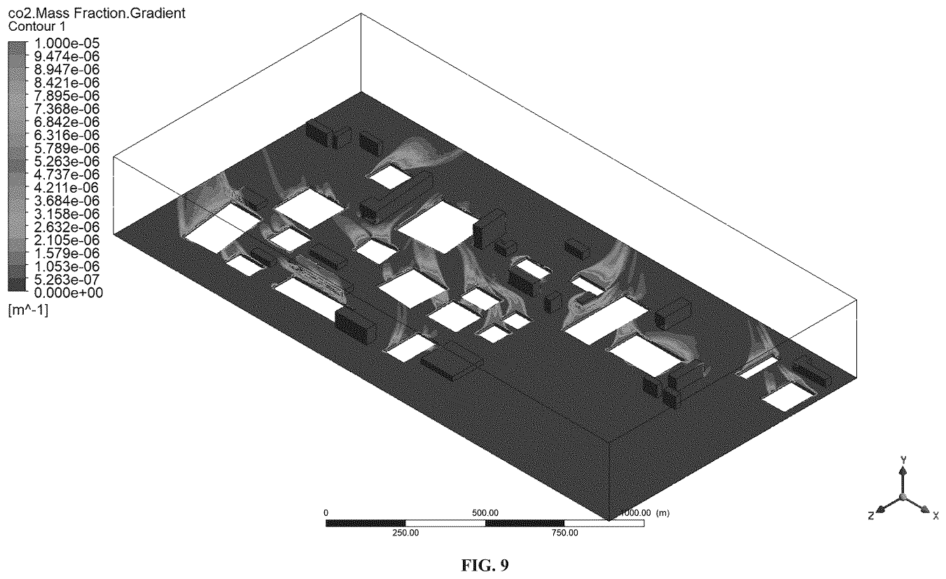

As shown in FIG. 9, obtaining the cloud diagram of greenhouse gas mass fraction and the velocity diagram of greenhouse gas emission on a certain section by simulation.

The present invention adopts a carbon measurement method for unorganized emissions of greenhouse gas in industrial parks, and the carbon measurement formula of greenhouse gas unorganized emission is:

$${F}_{total} = {V}_{greenhouse gas} \times {C}_{greenhouse gas}$$

Fₜₒₜₐₗ is carbon measurement of greenhouse gas;
V_{greehouse gas} is the greenhouse gas flow rate obtained by Ansys Fluent;
C_{greenhouse gas} is the greenhouse gas concentration monitored by the sensor.

The present invention adopts a carbon measurement method for unorganized emissions of greenhouse gas in industrial parks, by random forest machine, which can learn the quantification of importance based on the average impurity reduction to the important characteristic value, combining with cubic spline interpolation and BP neural network to optimize the interpolation thought, obtaining the influencing factors of high detection cost and ensuring that the data reduction degree of the influencing factors is more than 90%, as well as outputting the random forest prediction model with the strongest generalization ability and the evaluation report of the impact of meteorological environment on unorganized emissions, on this basis, through the weight analysis function, obtaining the input variables in the Ansys Fluent simulation model of unorganized emissions from the entire industrial park, making simulation on the greenhouse gas unorganized emission by combining Navier-Stokes equation and energy equation, thereby obtaining the greenhouse gas unorganized emission flow of industrial park at a certain moment, multiplying the concentration monitored by the sensor by the unorganized emission flow in the Ansys Fluent simulation model, obtaining the carbon emissions of greenhouse gas carbon emissions of the industrial park, thereby realizing the carbon measurement for unorganized emissions of greenhouse gas of the industrial park.

Therefore, the present invention adopts a carbon measurement method for unorganized emissions of greenhouse gas in industrial parks, which can solve the objective shortcomings of the existing technology, based on the historical unorganized emission data and meteorological data of the industrial park, combined with the thought of cubic spline interpolation, BP neural network and random forest algorithm, on this basis, combining the Ansys Fluent simulation model, which saves cost and achieves high-precision prediction, it can also train an unorganized emission prediction model with the strongest generalization ability, a reasonable environmental factor evaluation index, and realize the carbon measurement of unorganized emissions in industrial parks, it is also possible to predict the unorganized emissions of industrial parks at any time in the future and quantify the specific carbon emissions of industrial parks.

Finally, it should be noted that the above implementation examples are only used to explain the technical scheme of the invention rather than to restrict it, although the present invention is described in detail with reference to the better implementation examples, ordinary technicians in this field should understand that they can still modify or replace the technical scheme of the present invention, and these modifications or equivalent replacements cannot make the modified technical scheme out of the spirit and scope of the technical scheme of the present invention.

What is claimed is:

1. A carbon measurement method for unorganized emissions of greenhouse gas in an industrial park, comprising the following steps:
S1 obtaining historical meteorological data and historical carbon emission data of the industrial park, under a support of meteorological theory, dividing the historical meteorological data into three categories, and describing the historical meteorological data by cubic spline interpolation;
S2. based on classification, obtaining meteorological data, wherein the meteorological data are difficult to measure and have great influence by an interpolation surface, and inputting the obtained meteorological data into a back-propagation (BP) neural network for strengthening to obtain enhanced meteorological data.
S3. inputting the enhanced meteorological data into a random forest algorithm for an accurate prediction, determining whether a prediction accuracy meets needs of actual industrial parks and related industry standards and laws and regulations for unorganized emission monitoring, if the requirements are met, outputting prediction results and prediction models, wherein the prediction model is with a strongest generalization ability;
S4. according to different classifications, carrying out a weight analysis of an important degree quantitative index of an input parameters of Ansys Fluent;
S5. establishing an Ansys Fluent simulation model of industrial park, and importing parameters after a weight analysis into the Ansys Fluent simulation model;
S6. obtaining an unorganized emission flow of greenhouse gases at a predetermined time node in the industrial park, obtaining an unorganized emission concentration of greenhouse gases from a sensor, obtaining carbon emissions of the greenhouse gas in the industrial parks;
S7. outputting a random forest prediction model with a strongest generalization ability and an environmental impact factor evaluation report.

2. The carbon measurement method for the unorganized emissions of greenhouse gas in the industrial park according to claim 1, wherein three categories of meteorological data in step S1 comprise:
the first category: a sensible heat flux, a potential temperature gradient, a surface ripple ratio, a surface reflectivity at noon, an air temperature, a temperature measurement height, a humidity, a radiation loss rate, and a total heat release rate:
the second category: a surface friction velocity, a convective velocity scale, a convective boundary layer height, a mechanical atmospheric boundary layer height, a surface roughness, a wind speed, a wind direction, a wind measurement height, and a humidity;
the third category: a Mani length, a surface pressure, a low-capacity, a humidity, a temperature, an industrial park latitude and longitude, and an elevation.

3. The carbon measurement method for the unorganized emissions of greenhouse gas in the industrial park according to claim 2, wherein for the first category of meteorological data, the sensible heat flux is data having a greatest impact on the unorganized emissions, through a thought of interpolation, describing a sensible heat flux of temperature at a corresponding time node, by an interpolation surface, obtaining a sensible heat flux corresponding to a predetermined temperature value on the corresponding time node.

4. The carbon measurement method for the unorganized emissions of greenhouse gas in the industrial park according to claim 3, wherein for the second category of meteorological data, data with a greatest impact on the unorganized emissions are the surface friction velocity and the mechanical atmospheric boundary layer height, through the thought of interpolation, obtaining the surface friction velocity and the mechanical atmospheric boundary layer height of the wind speed at the corresponding time node, by an interpolation surface, obtaining the surface friction velocity and mechanical atmospheric boundary layer height under a predetermined wind speed condition at the corresponding time node.

5. The carbon measurement method for the unorganized emissions of greenhouse gas in the industrial park according to claim 4, wherein for the third category of meteorological data, the Mani length is data having a greatest impact on the unorganized emissions, using the thought of interpolation fitting, fitting out the Mani length of humidity at the corresponding time node, by the interpolation surface, obtaining the Mani length corresponding to a humidity value on the corresponding time node.

6. The carbon measurement method for the unorganized emissions of greenhouse gas in the industrial park according to claim 5, wherein the data enhancement of the BP neural network in step S2 is specified as:
putting the parameter values obtained by the interpolation surface into the whole category of meteorological factors respectively for learning reinforcement, repairing and strengthening missing data and error data that affect a key meteorology based on relevant meteorological theories, making a reduction degree of the missing data and error data reach more than 90%.

7. The carbon measurement method for the unorganized emissions of greenhouse gas in the industrial park according to claim 6, wherein the weight analysis in step S4 is specified as:
based on the prediction model in step S3 and the cubic spline interpolation function, combined with an average impurity reduction of random forest, quantifying an importance of important feature value, as well as the surface friction velocity, Mani length, sensible heat flux, and mechanical atmospheric boundary layer height obtained by the cubic spline interpolation, and the wind speed, wind direction, temperature and humidity measured by the sensor at a low cost, quantifying the surface friction velocity, the Mani length, the sensible heat flux, the mechanical atmospheric boundary layer height, the wind speed, the wind direction, the temperature, and the humidity into quantitative indicators based on the importance, and performing the weight analysis.

8. The carbon measurement method for the unorganized emissions of greenhouse gas in the industrial park according to claim 7, wherein in Step S5, by using a Navier-Stokes continuity equation, a Navier-Stokes momentum equation, an energy equation, relying on an Ansys Fluent simulation software, combined with the parameters obtained by the weight analysis, as an input of the model established by the Ansys Fluent simulation software, obtaining a fluid flow model of the unorganized emission in the industrial park.

9. The carbon measurement method for the unorganized emissions of greenhouse gas in the industrial park according to claim 7, wherein in Step S6, multiplying a specific flow value of the unorganized emissions at a predetermined moment with a concentration value of greenhouse gas unorganized emissions measured by the sensors, and obtaining a carbon measurement for the unorganized emissions of greenhouse gas in the industrial parks.
